(19) United States
(12) Patent Application Publication
(10) Pub. No.: US 2026/0156956 A1
(43) Pub. Date: Jun. 4, 2026

(54) WAFER LEVEL PACKAGING SYSTEMS AND RELATED METHODS

(71) Applicant: SEMICONDUCTOR COMPONENTS INDUSTRIES, LLC, Scottsdale, AZ (US)

(72) Inventors: Jorge LUBGUBAN, Danbury, CT (US); Gabrielle ROBERT, Fishkill, NY (US); Eric Jeffery WOOLSEY, Gilbert, AZ (US)

(73) Assignee: SEMICONDUCTOR COMPONENTS INDUSTRIES, LLC, Scottsdale, AZ (US)

(21) Appl. No.: 18/968,475

(22) Filed: Dec. 4, 2024

(51) Int. Cl. H10F 39/00; H10F 39/12

(52) U.S. Cl. CPC H10F 39/804; H10F 39/011; H10F 39/805; H10F 39/12

(57) ABSTRACT

An image sensor package may include an optically transmissive cover including a layer of silicon oxynitride thereon; an image sensor semiconductor die coupled to the optically transmissive cover through an adhesive; and at least one electrical connector included in the image sensor semiconductor die.

### BACKGROUND

### 1. Technical Field

Aspects of this document relate generally to devices for image sensing.

### 2. Background

Various semiconductor packages have been devised that help assist with making electrical connections between a semiconductor die and a circuit board or motherboard to which the semiconductor package has been attached. Some semiconductor package designs work to protect the semiconductor die from electrostatic discharge. Others work to protect the semiconductor die from shock or vibration.

### SUMMARY

An image sensor package may include an optically transmissive cover including a layer of silicon oxynitride thereon; an image sensor semiconductor die coupled to the optically transmissive cover through an adhesive; and at least one electrical connector included in the image sensor semiconductor die.

Implementations of an image sensor package may include one, all, or any of the following:

The layer of silicon oxynitride may be on a largest planar surface of the optically transmissive cover facing the image sensor semiconductor die.

The layer of silicon oxynitride may be on a largest planar surface of the optically transmissive cover opposite a largest planar surface facing the image sensor semiconductor die.

The refractive index of the layer of silicon oxynitride may substantially match a refractive index of the optically transmissive cover.

The package may include an antireflective coating coupled to the optically transmissive cover.

The antireflective coating may be directly coupled to the layer of silicon oxynitride which may be directly coupled to the optically transmissive cover.

The layer of silicon oxynitride may be patterned.

The pattern of the layer of silicon oxynitride may be only adjacent a perimeter of the optically transmissive cover.

The pattern of the layer of silicon oxynitride may be adjacent a perimeter of each of a plurality of semiconductor devices included in the image sensor semiconductor die.

Implementations of an image sensor package may include an optically transmissive cover including a layer of silicon dioxide thereon; an image sensor semiconductor die coupled to the optically transmissive cover through an adhesive; and at least one electrical connector included in the image sensor semiconductor die.

Implementations of an image sensor package may include one, all, or any of the following:

The layer of silicon dioxide may be on one of: a largest planar surface of the optically transmissive cover facing the image sensor semiconductor die; or a largest planar surface of the optically transmissive cover opposite a largest planar surface facing the image sensor semiconductor die.

The package may include an antireflective coating coupled to the optically transmissive cover.

The antireflective coating may be directly coupled to the layer of silicon dioxide which may be directly coupled to the optically transmissive cover.

The layer of silicon dioxide may be patterned.

The pattern may be only adjacent a perimeter of the optically transmissive cover.

The pattern may be adjacent a perimeter of each of a plurality of semiconductor devices included in the image sensor semiconductor die.

Implementations of a method of forming an image sensor package may include providing an optically transmissive substrate; forming one of a layer of silicon oxynitride or a layer of silicon dioxide on the optically transmissive substrate at a predetermined stress; and adjusting a warpage of the optically transmissive substrate using the predetermined stress. The method may include bonding a semiconductor substrate including a plurality of image sensor semiconductor die to the optically transmissive substrate; and singulating the semiconductor substrate and the optically transmissive substrate to form a plurality of image sensor packages.

Implementations of a method of forming an image sensor package may include one, all, or any of the following:

The method may include adjusting a warpage of the semiconductor substrate through the bonding.

The layer of silicon oxynitride may be on a largest planar surface of the optically transmissive substrate facing the semiconductor substrate or on a largest planar surface of the optically transmissive substrate opposite a largest planar surface facing the semiconductor substrate.

Forming the one of the layer of silicon oxynitride or layer of silicon dioxide further may include reaching the predetermined stress by increasing or decreasing a thickness of the layer of silicon oxynitride or of the layer of silicon dioxide at a constant layer refractive index.

Forming the layer of silicon oxynitride further may include adjusting a ratio of nitrogen during chemical vapor deposition to adjust a refractive index of the layer of silicon oxynitride.

The method may include forming a layer of antireflective coating over the layer of silicon oxynitride.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of an image sensor package;

FIG. 2 is a cross sectional view of another implementation of an image sensor package;

FIG. 3 is a diagram of an optically transmissive substrate coated on one largest planar surface with a silicon oxynitride film experiencing compressive stress and a semiconductor substrate experiencing tensile stress;

FIG. 4 is a diagram of an optically transmissive substrate coating on one largest planar surface with a silicon oxynitride film experiencing tensile stress and a semiconductor substrate experiencing compressive stress;

FIG. 5 is a top view of an implementation of an optically transmissive substrate with a ring of silicon oxynitride or silicon dioxide thereon;

FIG. 6 is a top view of another implementation of an optically transmissive substrate with a ring and grid of silicon oxynitride or silicon dioxide thereon;

FIG. 7 is a top view of an implementation of an optically transmissive cover with a silicon oxynitride or silicon dioxide layer formed adjacent to a perimeter of the optically transmissive cover; and

FIG. 8 is a side cross sectional view showing a curved image sensor made using an optically transmissive cover with a silicon oxynitride or silicon dioxide layer in compressive stress thereon.

### DESCRIPTION

This disclosure, its aspects and implementations, are not limited to the specific components, assembly procedures or method elements disclosed herein. Many additional components, assembly procedures and/or method elements known in the art consistent with the intended wafer level packaging systems and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such wafer level packaging systems and related methods, and implementing components and methods, consistent with the intended operation and methods.

When wafer level packaging a semiconductor substrate that includes various image sensor semiconductor devices, controlling the warpage of an optically transmissive substrate and of the semiconductor substrate is important during the bonding of the two substrates together. The warpage also affects the individual image sensor packages formed from the wafer level packaging process as differences in warpage can cause stress in the bond between the optically transmissive cover and the image sensor die and could lead to delamination. Immediate delamination leads to failures detected during package testing but delamination over time can lead to reliability problems with image sensor package.

The semiconductor substrates disclosed in this document may be made of various semiconductor materials, such as, by non-limiting example, silicon, silicon carbide, silicon on insulator, gallium arsenide, gallium nitride, sapphire, ruby, or any other semiconductor material type. Various optically transmissive substrates are also disclosed in this document that may be made of a wide variety of materials that are transparent, substantially transparent, or translucent to the particular wavelength of electromagnetic radiation to be detected by the image sensor device. A wide variety of wavelengths may be detected by the image sensor implementations disclosed herein, including, by non-limiting example, visible light, infrared light, ultraviolet light, X-rays, gamma rays, or any other wavelength of electromagnetic radiation. While the various image sensor packages disclosed herein utilize a single image sensor semiconductor die, in various system and method implementations disclosed herein the image sensor packages may include one or more image sensor semiconductor die and/or one or more other semiconductor die in adjacent or stacked/bonded configurations. These additional die may be digital signal processors, microprocessors, memory, or any other semiconductor die type for use in signal processing, storage, or data transmission. The principles disclosed herein may be employed with a wide variety of image sensor package types including where the semiconductor substrate is thinned prior to being bonded to the optically transmissive substrate.

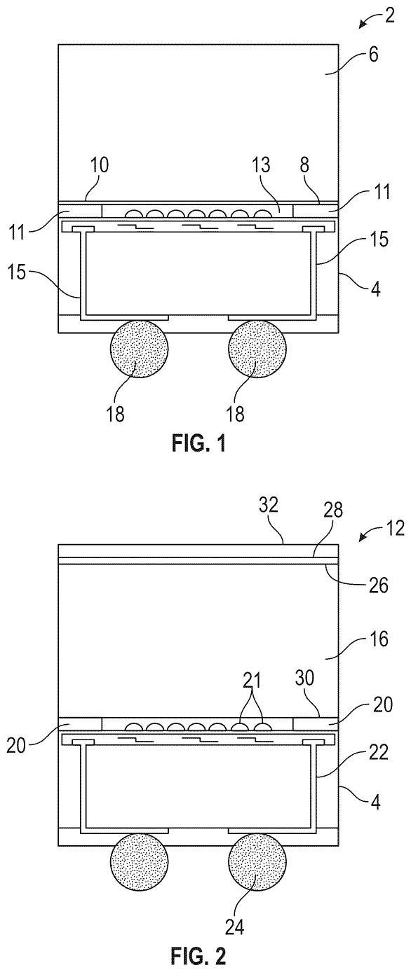

Referring to FIG. 1, a cross sectional view of an implementation of an image sensor package 2 is illustrated. In this implementation, an image sensor semiconductor die 4 is coupled/bonded to an optically transmissive cover 6. In this implementation, the bond is formed using dams 11 that extend around the perimeter of the image sensor semiconductor die 4 and form an air gap 13. However, in other image sensor implementations, no air gap may be present, and the image sensor package may be a gapless image sensor package type. In this image sensor package implementation, through silicon/through oxide vias 15 are used to form the electrical interconnects with balls 18 that serve to electrically connect the image sensor package 2 with a circuit board or motherboard during installation. However, in other implementations, wire bonds may be employed instead of or in addition to the through silicon/through oxide vias. In implementations where wire bonds are employed, the wire bonds may be located inside the material of the dams 11 to form a wire-in-dam package type. In other implementations, the wire bonds may be located outside the material of the dams 11. A wide variety of image sensor package configurations and corresponding electrical connectors may be created using the principles disclosed herein. The image sensor semiconductor die 4 may be made from any of the semiconductor substrate types disclosed in this document. The optically transmissive cover 6 may be made from any of the optically transmissive substrate type disclosed in this document.

As illustrated, a silicon oxynitride layer 8 is included on a largest planar side 10 of the optically transmissive cover 6 that faces the image sensor semiconductor die 4. While layer 10 is a silicon oxynitride (SiON) layer in the image sensor package implementation 2 of FIG. 1, in other implementations, layer 10 may be formed of silicon dioxide (SiO₂). In various implementations, the thickness of the silicon oxynitride or silicon dioxide layer ranges between about 0.5 microns to about 3 microns.

Referring to FIG. 2, another implementation of an image sensor package 12 is illustrated. This package implementation 2 also includes an image sensor semiconductor die 14 that is bonded to an optically transmissive cover 16. This image sensor package 12 also utilizes a dam 20 to form an air gapped image sensor package design in which is included a plurality of microlenses 21. In some implementations, microlenses may not be included. In other image sensor package implementations, a color filter array may be included either with or in place of the microlenses. This image sensor package 2 also utilizes through silicon vias 22 to form electrical connections with the balls 24, similar to the implementation of FIG. 2. However, in other implementations, the vias may be formed using a via in trench configuration where angled vias are formed in/on each side of the image sensor semiconductor die that facilitate an electrical connection between a top side pad and backside electrical interconnects. In other implementations, the image sensor semiconductor die may be connected to an interposer or substrate using wirebonds or pads which then handle electrical routing of signals. In yet other implementations, the image sensor semiconductor die may be connected to a leadframe using wirebonds or pads that handles electrical routing of signals. Many different image sensor package types may utilize the various principles disclosed in this document.

In the implementation of FIG. 2, a layer of silicon oxynitride 26 is formed on a largest planar surface 28 of the optically transmissive cover 16 that is opposite a largest planar surface 30 of the optically transmissive cover 16 that faces the image sensor semiconductor die 14. While in this implementation the use of silicon oxynitride for the material of the layer 26, in other implementations, silicon dioxide could be used. In various image sensor package implementations, as illustrated in FIG. 2, a layer of antireflective coating (ARC) material 32 is formed over the layer of silicon oxynitride 26. The material(s) used to form the layer(s) of antireflective coating may be, by non-limiting example, magnesium fluoride (MgF₂), titanium dioxide (TiO₂), hafnium oxide (HfO₂), silicon dioxide (SiO₂) and niobium oxide (Nb₂O₅), aluminum oxide (Al₂O₃) any combination thereof, or any other material with desired antireflective properties for the particular electromagnetic radiation wavelength(s) being sensed. The antireflective coating may include a layer of a single material, multiple layers of the same material, or multiple layers of different materials in various implementations.

In various image sensor package implementations, the use of a silicon oxynitride film can have some effect on light transmission through the optically transmissive cover 16 depending on the refractive index of the particular film and the refractive index of the material of the optically transmissive cover 16. To minimize the effect, matching of the refractive index can be done by varying the amount of nitrogen in the film during the deposition process. If chemical vapor deposition is used to deposit the silicon oxynitride film, this can be done by adjusting the amount of nitrogen gas in the deposition chamber during the deposition process. In other implementations that utilize sputtering, the amount of nitrogen can be adjusted by varying the amount of nitrogen in the sputtering target used to deposit the film. Other deposition methods may also be employed to form the silicon oxynitride film (atomic layer deposition, etc.) and corresponding adjustments can be made during these processes to adjust the nitrogen content of the film to adjust the resulting refractive index. In various implementations, the refractive index of the silicon oxynitride film can be adjusted from about 1.46 (about zero nitrogen) to about 2.1 (about zero oxygen) to reach a desired value. In some implementations, the desired value may be to match or substantially match the refractive index of the material of the optically transmissive cover 16. In other implementations, the desired value may be adjusted to a value intended to help set an overall refractive index of the stack of the silicon oxynitride layer 26 and the antireflective coating layer 32. In such implementations, the ultimate desired refractive index value may be a function of the refractive index of the material(s) used for the antireflective coating layer itself.

Where the material of the layer 26 is silicon dioxide, then the refractive index of the layer would be 1.46. The effect on light transmission of the layers 26, 32 can then be adjusted by adjusting the thickness of the layer and the thickness of the antireflective coating layer 32. Where an antireflective coating layer 32 is not used, the effect on light transmission of the layer 26 can be adjusted by adjusting the thickness of the silicon dioxide material itself. If the material of the optically transmissive cover 16 is glass, then the effect on light transmission of a silicon dioxide material used for layer 26 would be negligible as the indexes of refraction of both materials would be substantially the same regardless of the thickness of the silicon dioxide layer 26.

While the previous discussion has focused on refractive index effects and matching processes of the use of a silicon oxynitride/silicon dioxide film layer formed on the optically transmissive cover, the additional effect of using the films is to adjust the warpage of the optically transmissive cover. This effect is accomplished through use of various implementations of methods of forming an image sensor package which involve the process of forming the silicon oxynitride/silicon oxide layer with varying degrees of tensile or compressive stress. The amount of stress in the layer can vary between about 0 MPa to about 500 MPa for the silicon oxynitride film in the tensile direction and between about 0 MPa to about 300 MPa in the compressive direction. Whether the stress of the film is tensile or compressive is also determined for the silicon oxynitride film by the side of the optically transmissive cover that is coated. Also, the stress of the silicon oxynitride film can be increases as the film composition ratio approaches that of a silicon nitride film refractive index (as the oxygen ratio decreases). The amount of stress in the layer can vary between about 0 MPa to about 350 MPa in the compressive direction. This stress can be used to warp the optically transmissive cover in either direction depending on which side of the optically transmissive cover the silicon dioxide film is formed on.

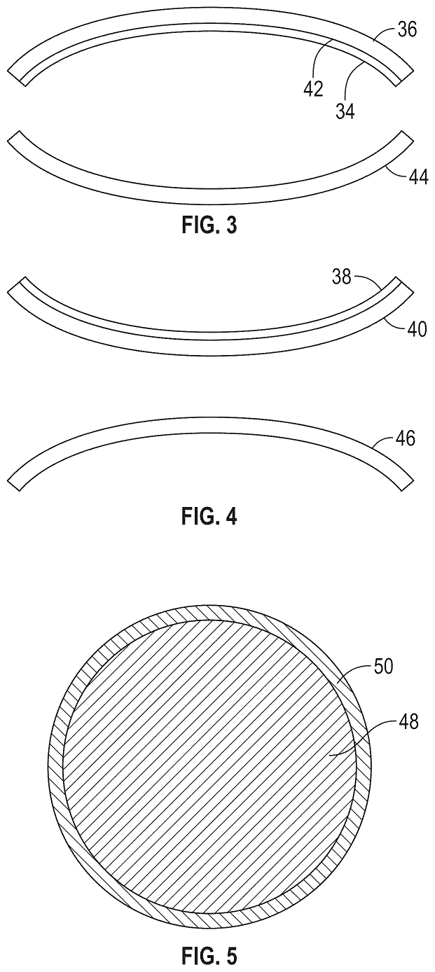

An implementation of a method of forming an image sensor package includes providing an optically transmissive substrate which may be formed of any substrate material disclosed herein. The shape of the optically transmissive substrate may correspond with the same of a semiconductor substrate to which it will ultimately be bonded in various method implementations. The method also includes forming a layer of silicon oxynitride or a layer of silicon dioxide on one of the largest planar surfaces of the optically transmissive substrate. In some implementations, both largest planar surfaces may include a layer of silicon oxynitride or silicon dioxide depending on the desired warpage effect desired. The method also includes adjusting the warpage of the optically transmissive substrate using a predetermined stress of the layer of silicon oxynitride or silicon dioxide. In various method implementations, the adjustment can be effected by adjusting the film thickness for films with the same refractive index value. In these implementations, the thicker the film, the more warpage can be induced. This predetermined stress is reached when the formation/deposition process of the layer of silicon oxynitride or silicon dioxide is completed. The stress of the layer of silicon oxynitride or silicon dioxide is adjusted by changing the deposition parameters used during the formation process. Some of these deposition parameters than can be adjusted to correspondingly adjust the amount of stress of the film include, by non-limiting example, deposition chamber pressure, deposition chamber temperature, chuck temperature, sputtering power, target distance, radio frequency power, the ratio between high frequency and low frequency radio frequency power, the total high frequency radio frequency power, the total low frequency radio frequency power, the gas mixture between silicon to oxygen to nitrogen introduced in to the chamber, and any other deposition parameter that can affect the ultimate stress of the as-formed film. Some or all of these deposition parameters can also be used to vary the direction of the stress of the film, whether compressive as in the silicon oxynitride film 34 illustrated in FIG. 3 formed on optically transmissive substrate 36 or tensile as in the silicon oxynitride film 38 illustrated in FIG. 4 formed on optically transmissive substrate 40.

Referring to FIGS. 3 and 4, whether the silicon oxynitride/silicon dioxide films generate warpage in the compressive or tensile directions may be enhanced by forming the films on different largest planar sides of the optically transmissive substrates 36, 40. In FIG. 3, the silicon oxynitride film 34 is formed on the largest planar side 42 of optically transmissive substrate 36 that faces the semiconductor substrate 44. In FIG. 4, the silicon oxynitride film 38 is formed on the largest planar side of the optically transmissive substrate 40 that faces away from the semiconductor substrate 46. Where a second layer is employed, that layer may be formed on the other largest planar surface with a stress that works in a corresponding direction to further assist in warping the substrate in the desired direction (tensile or compressive).

The ability to control the warpage of the optically transmissive substrates 36, 40 also provides the ability to control the warpage of the semiconductor substrates 44, 46 after the semiconductor substrates are bonded to the optically transmissive substrates 36, 40. The bonding process may be accomplished through a dam or blanket layer of an adhesive material selected to securely hold the material of the optically transmissive substrate to the material of the semiconductor substrates. This adhesive material may be thermally curable and/or curable using ultraviolet light in various package implementations. The ability to manage/correct the warpage of the semiconductor substrates 44, 46 may also be useful where the semiconductor substrates 44, 46 are thinned prior to bonding. The ability to manage the warpage may also be useful where the semiconductor substrates 44, 46 are thinned after bonding, where the removal of the substrate material can allow the stress of the other layers forming the image sensor devices to more effectively warp the thinned semiconductor substrate. The warpage of the optically transmissive substrates 36, 40 is then used to combat the now-freed stress of the image sensor layers after thinning to prevent warpage of image sensor packages after they are singulated from the material bonded optically transmissive substrates 36/semiconductor substrate 44 using a singulation process. The singulation process may be, by non-limiting example, sawing, lasering, water jet cutting, etching, scribing and breaking, any combination thereof, or any other process that can separate the material of the optically transmissive substrate and the material of the semiconductor substrate.

As illustrated in FIG. 3, the compressively stressed optically transmissive substrate 36, warped by the silicon oxynitride layer 34, can be bonded to the tensile stressed semiconductor substrate 44 to produce a bonded substrate that has balanced or substantially balanced stress throughout including in image sensor packages singulated therefrom. FIG. 4 illustrates how the tensile stressed optically transmissive substrate 40, warped by the silicon oxynitride layer 38, can be bonded to the compressively stressed semiconductor substrate 46 to also produce a bonded substrate that has balanced or substantially balanced stress throughout including in the image sensor packages singulated therefrom. This ability to manage the stress of the substrates and the singulated image sensor packages may assist with improving processing and reduce yield and/or reliability losses due to package delamination as previously discussed.

Where an antireflective coating is also employed, that antireflective coating may have its own particular stress. In various method implementations, the method includes adjusting the warpage of the optically transmissive substrate using the layer of silicon oxynitride or silicon dioxide so that any warpage of the antireflective coating either is complementary to the warpage induced or compensated for. In this way, the use of the antireflective coating can enhance the warpage control effect or the coating's effect on the warpage can be managed using the silicon oxynitride/silicon dioxide layers.

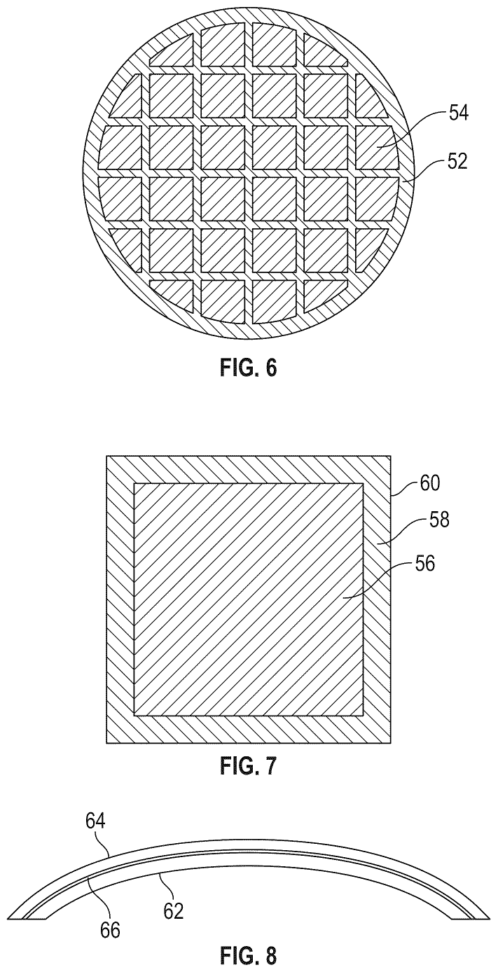

Up to this point, the use of blanket layers of silicon oxynitride or silicon dioxide on optically transmissive covers and optically transmissive substrates has been discussed. In various other package and method implementations, patterned layers of silicon oxynitride or silicon dioxide may be employed to achieve the desired warpage effect of the optically transmissive substrates prior to and after singulation. Referring to FIG. 5, a top view of an implementation of an optically transmissive substrate 48 is illustrated with a patterned silicon oxynitride layer 50 thereon which extends adjacent to a perimeter of the substrate 48. Because in this implementation the optically transmissive substrate 48 is circular/elliptical, the patterned silicon oxynitride layer 50 takes the form of a ring. In various methods of forming an image sensor package, the ring can be formed in one implementation by first depositing the silicon oxynitride layer 48 over the entire surface of the optically transmissive substrate 48. A layer of photoresist or another photodefinable material is then deposited over the silicon oxynitride layer 48 followed by an exposure and develop step that leaves the photoresist/photodefinable material remaining over the area of the ring illustrated in FIG. 5. An etching process is then used to remove the exposed silicon oxynitride layer from the surface of the optically transmissive substrate 48. A suitable removal process for the photoresist/photodefinable material from the surface of the ring is then carried out. Where the optically transmissive substrate 48 is thinned relative to a full thickness of a comparably sized silicon wafer, the remaining ring of silicon oxynitride material 50 may be effective to induce the desired warpage in the substrate. Even where the optically transmissive substrate 48 is not thinned, the stress in the ring of silicon oxynitride material 50 applied around the perimeter of the substrate may be effective to induce the desired warpage in the substrate (whether compressive or tensile. In this implementation, since the width of the ring may be equivalent to or substantially equivalent to a width of an edge bead exclusion region of a semiconductor substrate to which the optically transmissive substrate 58 is bonded, the resulting singulated image sensor packages would not include a layer of silicon oxynitride over any part of the optically transmissive cover included in each package. The implementation of FIG. 5 may be useful where the need for warpage control is during wafer/substrate level packaging operations and not at the finished package level.

Where warpage control at the finished package level (or greater warpage control than can be achieved using a ring) is desired, the silicon oxynitride layer can be patterned to include a grid. Referring to FIG. 6, a patterned silicon oxynitride layer 52 is illustrated formed over optically transmissive substrate 54. The gridlines of the grid of the patterned silicon oxynitride layer 52 in this implementation are placed at locations that will be placed over perimeters of adjoining image sensor semiconductor die included in the semiconductor substrate to which the optically transmissive substrate 54 is bonded. The method of making the patterned silicon oxynitride layer 52 is similar to that described with respect to the implementation of FIG. 5 using a photodefinable material and etching process. The use of the grid pattern means that, if the grid lines are sufficiently wide, a portion of each grid line will be present on each side of each optically transmissive cover singulated from the optically transmissive substrate. FIG. 7 illustrates an optically transmissive cover 56 post-singulation coupled to an image sensor die (not shown) and the layer of silicon oxynitride 58 that extends adjacent the perimeter 60 of the cover. If the grid lines in FIG. 6 are suitably wide, the width of the layer of silicon oxynitride 58 from the perimeter can be set so that the layer extends only across non-active regions covered by the optically transmissive cover 56 (pads, wirebonds, etc.) around a pixel array exposed through the cover. This configuration may essentially eliminate any refractive index difference effects resulting from the use of the silicon oxynitride layer 58 on any electromagnetic radiation passing through the optically transmissive cover 56 while providing desired warpage adjustment/control for the finished image sensor package.

While in the implementations illustrated in FIGS. 5-7 the use of a silicon oxynitride material has been described, the same principles apply if a silicon dioxide material was used. Similar ring configurations and ring and grid combinations could be utilized in various implementations. Also, various other patterns for the silicon oxynitride/silicon dioxide layer could be employed in various implementations in addition to those illustrated in FIGS. 5-7 including, by non-limiting example, dots, diagonals, spirals, ellipses, squares, rectangles, circles, or any other pattern of closed shapes, or any other closed shape.

Up to this point the discussion has focused on the use of warping of the optically transmissive substrate to counter a warpage of a semiconductor substrate to which it is bonded. However, in other image sensor package and method implementations, the warpage of the optically transmissive substrate may be used to create a desired permanent warpage of the optically transmissive substrate and/or image sensor package to which a warped optically transmissive cover is bonded. Referring to FIG. 8, an implementation of an image sensor semiconductor die 62 is illustrated which is bonded to optically transmissive cover 64 which is warped by a tensile stressed oxynitride layer 66. Because of the use of the stressed oxynitride layer 66, the warpage of the optically transmissive cover 64 is maintained and, through the bonding to the image sensor semiconductor die 62, maintains the desired warpage of the resulting image sensor package. Because the warpage of the optically transmissive cover can be significant in a cylindrical or spherical direction depending upon the shape of the substrate/semiconductor die, in various method implementations, the formation of the stressed oxynitride layer 66 may take place after formation of the optically transmissive cover 64 prior to bonding. The resulting warped optically transmissive cover 64 is then bonded to the singulated image sensor semiconductor die 62 using a support or other jig designed to hold the cover and die together until the adhesive used is cured. The resulting warped/curved image sensor package is then ready for subsequent processing steps or for installation in a desired location. The ability to create curved image sensors at a controlled and desired warpage level using a silicon oxynitride or silicon dioxide layer may be useful in a wide variety of applications, including, by non-limiting example, light detection and ranging (LIDAR) sensors, medical device imaging sensors, light sensors, radar sensors, or any other sensor type where a curved image sensor is needed.

In places where the description above refers to particular implementations of wafer level packaging systems and related methods and implementing components, sub-components, methods and sub-methods, it should be readily apparent that a number of modifications may be made without departing from the spirit thereof and that these implementations, implementing components, sub-components, methods and sub-methods may be applied to other wafer level packaging systems and related methods.

What is claimed is:

1. An image sensor package comprising:
an optically transmissive cover comprising a layer of silicon oxynitride thereon;
an image sensor semiconductor die coupled to the optically transmissive cover through an adhesive; and
at least one electrical connector comprised in the image sensor semiconductor die.

2. The package of claim 1, wherein the layer of silicon oxynitride is on a largest planar surface of the optically transmissive cover facing the image sensor semiconductor die.

3. The package of claim 1, wherein the layer of silicon oxynitride is on a largest planar surface of the optically transmissive cover opposite a largest planar surface facing the image sensor semiconductor die.

4. The package of claim 1, wherein a refractive index of the layer of silicon oxynitride substantially matches a refractive index of the optically transmissive cover.

5. The package of claim 1, further comprising an antireflective coating coupled to the optically transmissive cover.

6. The package of claim 5, wherein the antireflective coating is directly coupled to the layer of silicon oxynitride which is directly coupled to the optically transmissive cover.

7. The package of claim 1, wherein the layer of silicon oxynitride is patterned.

8. The package of claim 7, wherein the pattern of the layer of silicon oxynitride is only adjacent a perimeter of the optically transmissive cover.

9. The package of claim 8, wherein the pattern of the layer of silicon oxynitride is adjacent a perimeter of each of a plurality of semiconductor devices comprised in the image sensor semiconductor die.

10. An image sensor package comprising:
an optically transmissive cover comprising a layer of silicon dioxide thereon;
an image sensor semiconductor die coupled to the optically transmissive cover through an adhesive; and
at least one electrical connector comprised in the image sensor semiconductor die.

11. The package of claim 10, wherein the layer of silicon dioxide is on one of:
a largest planar surface of the optically transmissive cover facing the image sensor semiconductor die; or
a largest planar surface of the optically transmissive cover opposite a largest planar surface facing the image sensor semiconductor die.

12. The package of claim 10, further comprising an antireflective coating coupled to the optically transmissive cover.

13. The package of claim 12, wherein the antireflective coating is directly coupled to the layer of silicon dioxide which is directly coupled to the optically transmissive cover.

14. The package of claim 10, wherein the layer of silicon dioxide is patterned and where:
the pattern is only adjacent a perimeter of the optically transmissive cover; or
the pattern is adjacent a perimeter of each of a plurality of semiconductor devices comprised in the image sensor semiconductor die.

15. A method of forming an image sensor package, the method comprising:
providing an optically transmissive substrate;
forming one of a layer of silicon oxynitride or a layer of silicon dioxide on the optically transmissive substrate at a predetermined stress;
adjusting a warpage of the optically transmissive substrate using the predetermined stress;
bonding a semiconductor substrate comprising a plurality of image sensor semiconductor die to the optically transmissive substrate; and
singulating the semiconductor substrate and the optically transmissive substrate to form a plurality of image sensor packages.

16. The method of claim 15, further comprising adjusting a warpage of the semiconductor substrate through the bonding.

17. The method of claim 15, wherein the layer of silicon oxynitride is one of:
on a largest planar surface of the optically transmissive substrate facing the semiconductor substrate; or
on a largest planar surface of the optically transmissive substrate opposite a largest planar surface facing the semiconductor substrate.

18. The method of claim 15, wherein forming the one of the layer of silicon oxynitride or layer of silicon dioxide further comprises reaching the predetermined stress by increasing or decreasing a thickness of the layer of silicon oxynitride or of the layer of silicon dioxide at a constant layer refractive index.

19. The method of claim 15, wherein forming the layer of silicon oxynitride further comprises adjusting a ratio of nitrogen during chemical vapor deposition to adjust a refractive index of the layer of silicon oxynitride.

20. The method of claim 15, further comprising forming a layer of antireflective coating over the layer of silicon oxynitride.
